(19) United States
(12) Patent Application Publication
(10) Pub. No.: US 2024/0307909 A1
(43) Pub. Date: Sep. 19, 2024

(54) WINDOW DEPOSITION APPARATUS

(71) Applicant: SAMSUNG DISPLAY CO., LTD., YONGIN-SI (KR)

(72) Inventors: SEONGSIK CHOI, YONGIN-SI (KR); JAEHONG KIM, YONGIN-SI (KR); CHAEKYEONG LEE, YONGIN-SI (KR); JONGSEOK JOO, YONGIN-SI (KR); SUNGWOO KIM, YONGIN-SI (KR); WON-JONG BAEK, YONGIN-SI (KR)

(21) Appl. No.: 18/393,624

(22) Filed: Dec. 21, 2023

(30) Foreign Application Priority Data
Mar. 13, 2023 (KR) 10-2023-0032531

(51) Int. Cl. B05B 16/40; B05B 13/02

(52) U.S. Cl. CPC B05B 16/40; B05B 13/0292; B05B 16/80

(57) ABSTRACT

A window deposition apparatus includes a chamber, a seating part disposed in the chamber and on which a window is disposed and in which an open portion that exposes a portion of the window is formed, and a spray part disposed in the chamber and that faces a bottom surface of the seating part. An inner surface of the seating part that defines the open portion includes a first inner surface, an inducing surface that connects the first inner surface and the bottom surface of the seating part to each other, a second inner surface disposed on the first inner surface, and a guide surface that connects the second inner surface and a top surface of the seating part to each other. The first inner surface protrudes inward from the second inner surface.

### CROSS-REFERENCE TO RELATED APPLICATIONS

This U.S. non-provisional patent application claims priority under 35 U.S.C. § 119 from Korean Patent Application No. 10-2023-0032531, filed on Mar. 13, 2023 in the Korean intellectual Property Office, the contents of which are herein incorporated by reference in their entirety.

### TECHNICAL FIELD

Embodiments of the present disclosure herein are directed to a window deposition apparatus.

### DISCUSSION OF THE RELATED ART

Display devices, such as televisions, monitors, smartphones and tablet computers, which provide an image to a user, include a display panel that displays the image. Examples of display panels include a liquid crystal display panel, an organic light emitting display panel, an electro-wetting display panel, and an electrophoretic display panel.

A surface of a window needs to be uniform and transparent so that a user can see the user's input or a device's output. Accordingly, an anti-reflective layer, etc., may be deposited on the window.

### SUMMARY

Embodiments of the present disclosure provides a window deposition apparatus that prevents a deposition material from being deposited on a rear surface of a window when the deposition material is sprayed toward a window disposed on a seating part, thereby mitigating a defect rate of the window.

An embodiment of the inventive concept provides a window deposition apparatus that includes a chamber, a seating part disposed within the chamber and on which a window is disposed and in which an open portion that exposes a portion of the window is formed, and a spray part disposed within the chamber and that faces a bottom surface of the seating part. An inner surface of the seating part that defines the open portion includes a first inner surface that defines the open portion, an inducing surface that connects the first inner surface and the bottom surface of the seating part to each other, a second inner surface disposed on the first inner surface, and a guide surface that connects the second inner surface and a top surface of the seating part to each other. The first inner surface protrudes inward from the second inner surface.

In an embodiment of the inventive concept, a window deposition apparatus includes a chamber, a seating part disposed within the chamber and on which a window is disposed and in which an open portion that exposes a portion of the window is formed, and a spray part disposed within the chamber and that faces a bottom surface of the seating part. An inner surface of the seating part that defines the open portion includes a first inner surface that defines the open portion, a second inner surface disposed on the first inner surface, and a seating surface that connects an upper end of the first inner surface and a lower end of the second inner surface to each other. The first inner surface protrudes inward from the second inner surface.

### BRIEF DESCRIPTION OF THE DRAWINGS

FIG. 1 illustrates a window deposition apparatus according to an embodiment of the inventive concept.

FIG. 2 illustrates a seating part of FIG. 1.

FIG. 3 illustrates a first region AA1 in FIG. 2.

FIG. 4 is a cross-sectional view taken along line I-I′ in FIG. 3.

FIG. 5 is a cross-sectional view taken along line II-II′ in FIG. 3.

FIG. 6 illustrates a display device manufactured by a window deposition apparatus of FIG. 1;

FIG. 7 is a cross-sectional view taken along line III-III′ in FIG. 6.

FIG. 8 illustrates a window module of FIG. 7.

FIGS. 9A to 9C illustrate deposition of the window module of FIG. 8.

FIG. 10A illustrates a window module according to a Comparative Example.

FIG. 10B illustrates a window module manufactured by a window deposition apparatus according to an embodiment of the inventive concept.

FIGS. 11A and 11B illustrate adhesion between a window module and a second adhesive layer.

### DETAILED DESCRIPTION

Features of the present disclosure, and implementation methods thereof will be clarified through embodiments described in detail with reference to the accompanying drawings. Embodiments of the present disclosure may, however, take different forms and should not be construed as limited to the embodiments set forth herein. Like reference numerals may refer to like elements throughout.

When an element or layer is referred to as being “on” another element or layer, it may be directly on the other element or layer or a third element or layer may be interposed between the elements or layers.

The term “about” as used herein is inclusive of the stated value and means within an acceptable range of deviation for the particular value as determined by one of ordinary skill in the art, considering the measurement in question and the error associated with measurement of the particular quantity, such as the limitations of the measurement system. For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art.

Hereinafter, embodiments of the inventive concept will be described in more detail with reference to the accompanying drawings.

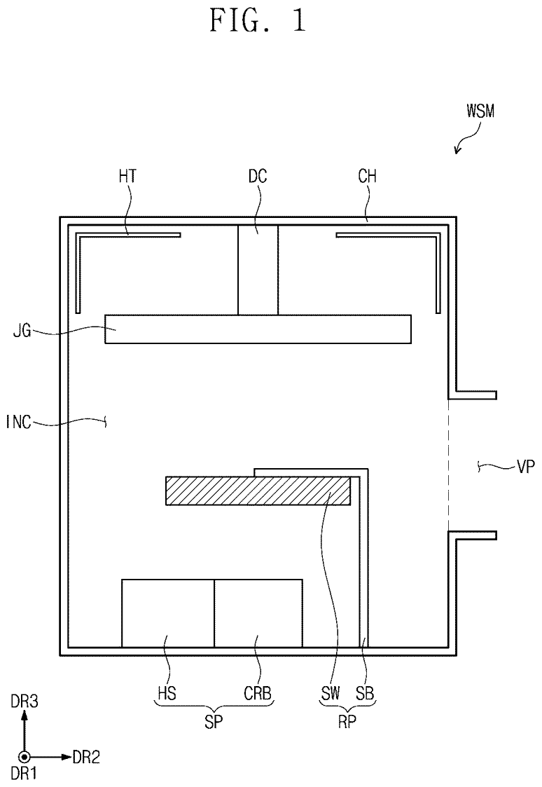

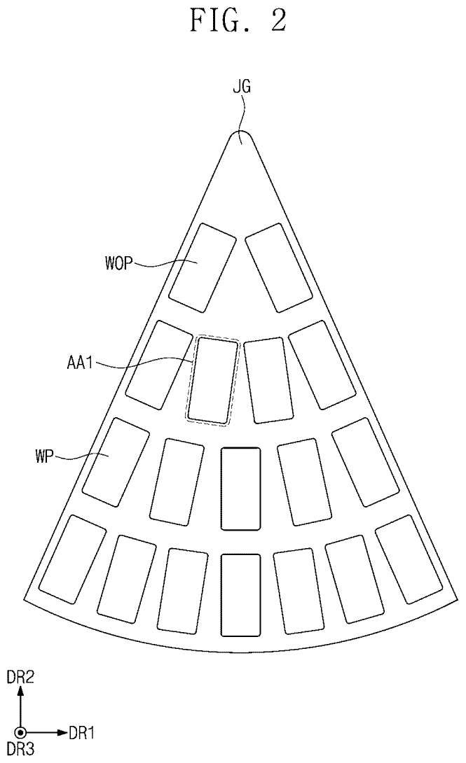

FIG. 1 illustrates a window deposition apparatus according to an embodiment of the inventive concept. FIG. 2 illustrates a seating part of FIG. 1.

For example, FIG. 2 is a plan view.

Referring to FIG. 1, in an embodiment, a window deposition apparatus WSM includes a chamber CH, heating parts HT, a driving part DC, a seating part JG, a rotary part RP, a vacuum part VP, and a spray part SP.

For example, the chamber CH in FIG. 1 has a rectangular shape when viewed in a first direction DR1. However, an embodiment of the inventive concept is not necessarily limited thereto, and the chamber CH may have various shapes in other embodiments.

The chamber CH provides an inner space INC. The vacuum part VP is connected to one of two sides of the chamber CH that are opposite to each other in a second direction DR2 that crosses the first direction DR1. The vacuum part VP extends from the one side of the chamber CH in the second direction DR2. The one side of the chamber CH is a adjacent to the rotary part RP to be described below. The vacuum part VP maintains the inner space INC of the chamber CH to be in a vacuum state.

Hereinafter, a third direction DR3 is defined as a direction substantially perpendicularly to a plane defined by the first direction DR1 and the second direction DR2. The statement “in a plan view” used herein refers to a state of being viewed in the third direction DR3.

The heating parts HT, the driving part DC, the seating part JG, the rotary part RP, and the spray part SP are disposed in the inner space INC.

The spray part SP is adjacent to a lower portion of the chamber CH. The spray part SP is disposed on a bottom surface of the chamber CH when viewed in the first direction DR1.

The spray part SP includes a heat source HS and a crucible CRB. For example, the heat source HS and the crucible CRB are adjacent to each other in the second direction DR2.

A deposition material may be disposed in the crucible CRB. The heat source HS heats the deposition material disposed in the crucible CRB. For example, the heat source HS heats the crucible CRB through one of an evaporation method that converts kinetic energy of electrons into thermal energy, or a sputtering method that converts electrical energy of a plasma into kinetic energy.

Referring to FIGS. 1 and 2, in an embodiment, the seating part JG is adjacent to an upper portion of the inner space INC. The seating part JG is disposed above the spray part SP. The spray part SP faces a bottom surface of the seating part JG.

For example, the seating part JG has a fan shape when viewed in a plan view. However, the shape of the seating part JG is not necessarily limited thereto and may have other shapes in other embodiments.

A plurality of open portions WOP are formed in the seating part JG. For example, the open portions WOP are formed in a plurality of rows. For example, the rows correspond to the second direction DR2. The number of the open portions WOP formed in a k-th row is greater than the number of the open portions WOP formed in a (k+1)th row in a second direction DR2 order. Here, k is a positive integer of 1 or more.

For example, seven open portions WOP are formed in a first row, five open portions WOP are formed in a second row, four open portions WOP are formed in a third row, and two open portions WOP are formed in a fourth row.

For example, each of the open portions WOP has a rectangular shape when viewed in a plan view. However, an embodiment of the inventive concept is not necessarily limited thereto, and in other embodiments, the open portions WOP have other shapes.

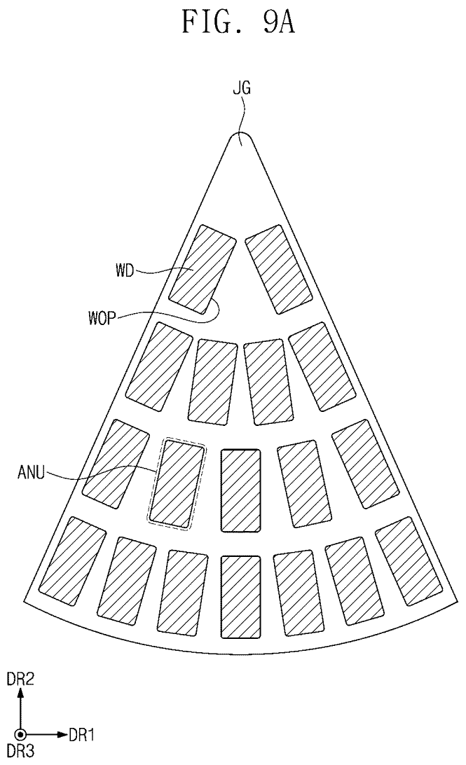

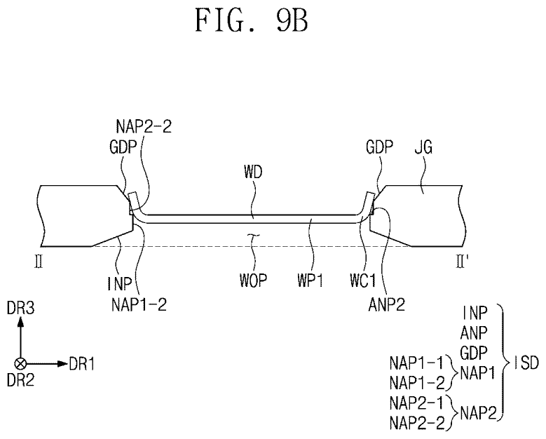

Windows WD (see FIG. 8) to be described below are disposed in the open portions WOP, respectively. The arrangement of the windows WD (see FIG. 8) will be described in detail with reference to FIGS. 9A and 9B.

Referring to FIG. 1, the driving part DC is disposed on the seating part JG. The seating part JG is rotatably coupled to the driving part DC. A motor is disposed inside the driving part DC. Accordingly, the driving part DC can rotate the seating part JG.

The rotary part RP is disposed between the seating part JG and the spray part SP. The rotary part RP includes a wing part SW and a support SB. The support SB extends from a bottom surface of the inner space INC in each of the third direction DR3 and the second direction DR2. The support SB has a shape that is similar to a letter “L” when viewed in the first direction DR1.

The wing part SW is disposed above the crucible CRB. The wing part SW is rotatably coupled to the support SB. A motor is disposed inside the support SB. Accordingly, the wing part SW can rotate. As the wing part SW rotates, the deposition material discharged from the crucible CRB is uniformly spread out on the seating part JG. This will be described in detail with reference to FIG. 9C.

The heating parts HT are disposed in the inner space INC. The heating parts HT are adjacent to the upper portion of the inner space INC. For example, the heating parts HT are symmetrically disposed to each other in the second direction DR2.

The heating parts HT maintain a temperature of the inner space INC. For example, the heating parts HT maintain the temperature of the inner space INC at a set temperature through radiant heat.

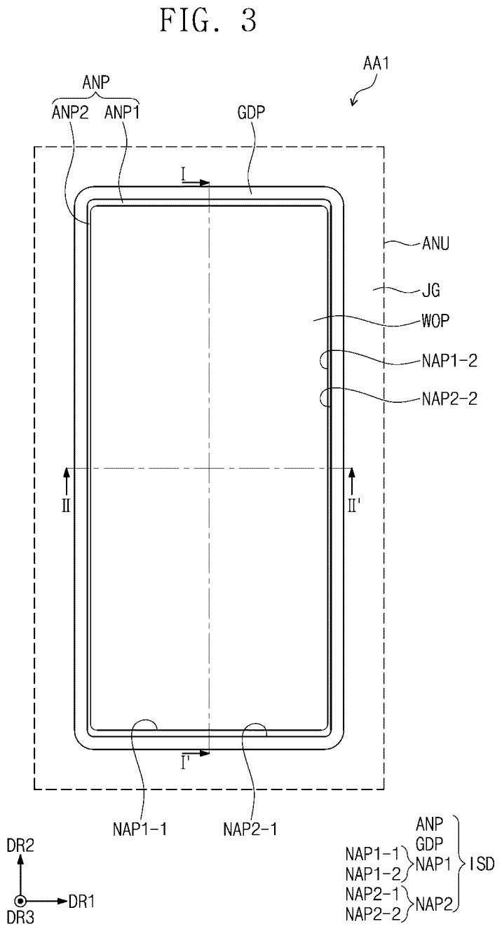

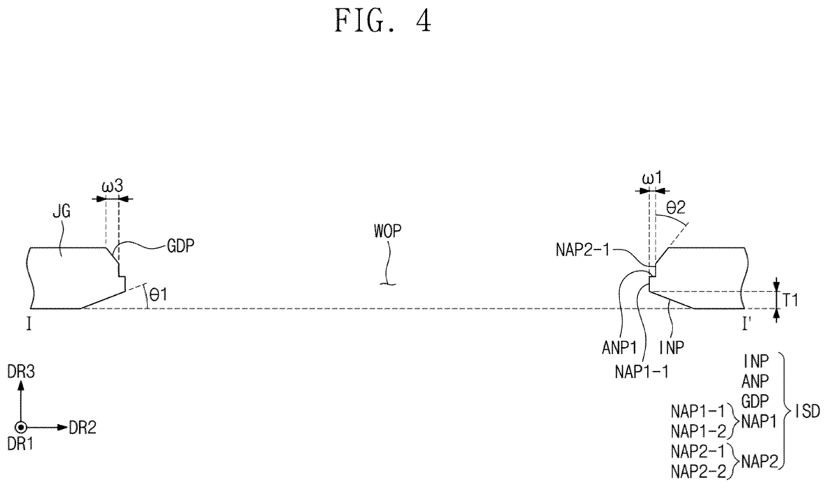

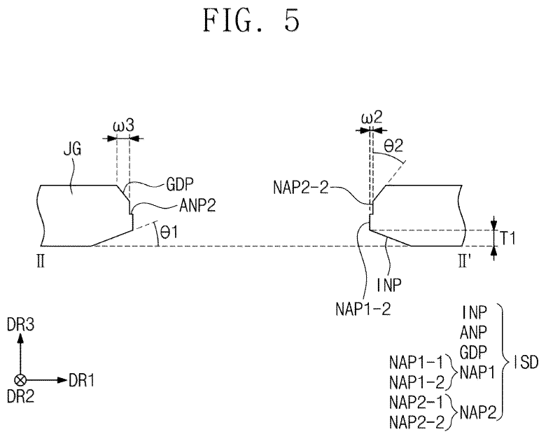

FIG. 3 illustrates a first region AA1 in FIG. 2. FIG. 4 is a cross-sectional view taken along line I-I′ in FIG. 3. FIG. 5 is a cross-sectional view taken along line II-II′ in FIG. 3.

For example, FIG. 3 is an enlarged plan view.

Referring to FIGS. 2 and 3, in an embodiment, an open portion WOP and a portion of the seating part JG in which the open portion WOP is formed may be defined as a seating unit ANU. Hereinafter, one seating unit ANU will be described.

The seating unit ANU has a frame shape when viewed in a plan view. The seating unit ANU has an inner surface ISD that defines the open portion WOP. The inner surface ISD surrounds the open portion WOP when viewed in a plan view.

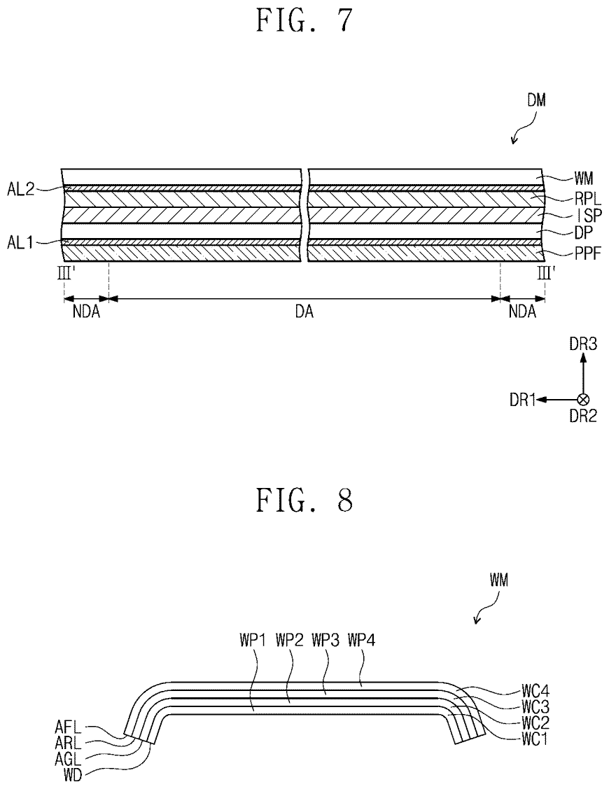

A window WD (see FIG. 7) to be described below is disposed in the open portion WOP. This will be described in detail with reference to FIGS. 9A and 9B.

The inner surface ISD includes a first inner surface NAP1, a second inner surface NAP2, a seating surface ANP, and a guide surface GDP. The guide surface GDP may surround the seating surface ANP, the first inner surface NAP1, and the second inner surface NAP2 when viewed on a plan view.

Referring to FIGS. 3 to 5, in an embodiment, the inner surface ISD further includes an inducing surface INP. The inducing surface INP connects the bottom surface of the seating part JG and the first inner surface NAP1 to each other. The inducing surface INP is inclined with respect to the bottom surface of the seating part JG. The inducing surface INP has a height that gradually increases toward the first inner surface NAP1.

The inducing surface INP has a predetermined angle with respect to the bottom surface of the seating part JG. The inducing surface INP has an angle θ1 of about 20 degrees or greater and less than about 90 degrees with respect to the bottom surface of the seating part JG. The inducing surface INP has a thickness T1 of about 3 mm to about 5 mm in the third direction DR3. The thickness of the inducing surface INP is defined as a length in the third direction DR3 from the bottom surface of the seating part JG to a boundary between the inducing surface INP and the first inner surface NAP1.

The deposition material can move along the inducing surface INP toward the window WD (see FIG. 8) disposed in the open portion WOP. Accordingly, the deposition material and the window WD (see FIG. 8) may be in contact with each other. This will be described in detail with reference to FIGS. 9B and 9C.

The first inner surface NAP1 includes first-1 inner surfaces NAP1-1 and first-2 inner surfaces NAP1-2. The first-1 inner surfaces NAP1-1 may extend in the first direction DR1. The first-1 inner surfaces NAP1-1 face each other in the second direction DR2.

The first-2 inner surfaces NAP1-2 extend in the second direction DR2. Each of the first-2 inner surfaces NAP1-2 extends in the second direction DR2 from one of the first-1 inner surfaces NAP1-1. Each of the first-2 inner surfaces NAP1-2 extends from the one first-1 inner surface NAP1-1 toward the other of the first-1 inner surfaces NAP1-1. Each of the first-1 inner surfaces NAP1-1 and each of the first-2 inner surfaces NAP1-2 are connected to each other. The first-2 inner surfaces NAP1-2 face each other in the first direction DR1. Accordingly, each of the first-2 inner surfaces NAP1-2 connects the first-1 inner surfaces NAP1-1 to each other. For example, the first-1 inner surfaces NAP1-1 and the first-2 inner surfaces NAP1-2 are provided as one integrated body.

The second inner surface NAP2 is disposed on the first inner surface NAP1. The first inner surface NAP1 further protrudes from the second inner surface NAP2 toward the inside of the open portion WOP. The first inner surface NAP1 and the second inner surface NAP2 have a stepped shape with a height difference.

The second inner surface NAP2 includes a second-1 inner surface NAP2-1 and a second-2 inner surface NAP2-2. The second-1 inner surface NAP2-1 is disposed on the first-1 inner surface NAP1-1. The second-1 inner surface NAP2-1 extends in the first direction DR1.

The second-2 inner surface NAP2-2 is disposed on the first-2 inner surface NAP1-2. The second-2 inner surface NAP2-2 extends in the second direction DR2.

The seating surface ANP connects the first inner surface NAP1 and the second inner surface NAP2 to each other. The seating surface ANP connects an upper end of the first inner surface NAP1 and a lower end of the second inner surface NAP2 to each other. The window WD (see FIG. 8) to be described below is disposed on the seating surface ANP. The seating surface ANP supports the window WD (see FIG. 8). This will be described in detail with reference to FIG. 9B.

The seating surface ANP includes first seating surfaces ANP1 and second seating surfaces ANP2. Each of the first seating surfaces ANP1 connects the first-1 inner surface NAP1-1 and the second-1 inner surface NAP2-1 to each other. The first seating surfaces ANP1 extend in the first direction DR1 when viewed in a plan view. For example, each of the first seating surfaces ANP1 has a width ω1 in the second direction DR2 of about 0.2 mm to about 0.3 mm.

Each of the second seating surfaces ANP2 connects the first-2 inner surface NAP1-2 and the second-2 inner surface NAP2-2 to each other. The second seating surfaces ANP2 extend in the second direction DR2 when viewed in a plan view. For example, each of the second seating surfaces ANP2 may have a width ω2 in the first direction DR1 of about 0.15 mm to about 0.25 mm.

The guide surface GDP connects the second inner surface NAP2 and a top surface of the seating part JG to each other. The guide surface GDP is inclined with respect to the top surface of the seating part JG. The guide surface GDP has a height that gradually decreases toward the second inner surface NAP2. Accordingly, the window WD (see FIG. 8) can move along the guide surface GDP to be disposed in the open portion WOP. The window WD (see FIG. 8) is disposed on the seating surface ANP along the guide surface GDP.

The guide surface GDP has a predetermined angle with respect to the top surface of the seating part JG. For example, the guide surface GDP has an angle θ2 of about 20 degrees or greater and less than about 90 degrees in the third direction DR3. The guide surface GDP has a width ω3 in the first direction DR1 or the second direction DR2 of about 3 mm to about 7 mm when viewed in a plan view.

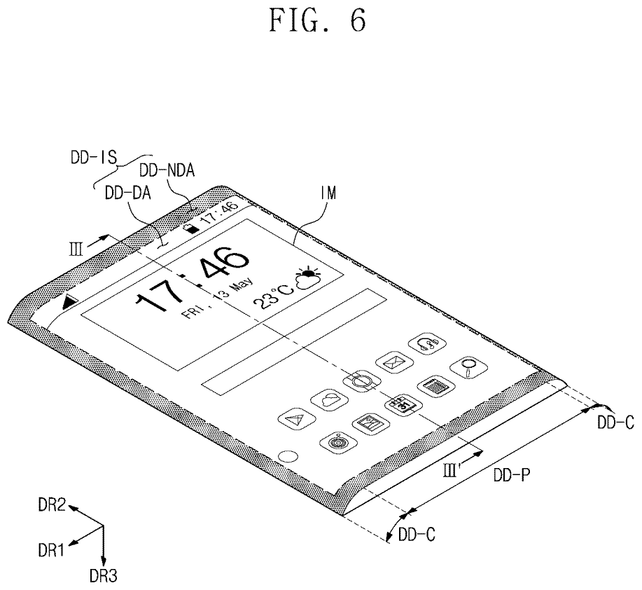

FIG. 6 illustrates a display device manufactured by the window deposition apparatus illustrated in FIG. 1.

Referring to FIG. 6, in an embodiment, a display device DD has a rectangular shape with short sides that extend in the first direction DR1 and long sides that extend in the second direction DR2 when viewed in a plan view. However, an embodiment of the inventive concept is not necessarily limited thereto, and in other embodiments, the display device DD can have various other shapes, such as a circular shape or a polygonal shape.

The display device DD can display an image IM through a display surface DD-IS. The display surface DD-IS is divided into different regions according to whether or not the image IM can be displayed. The display surface DD-IS includes a display region DD-DA, in which the image IM can be displayed, and a non-display region DD-NDA adjacent to the display region DD-DA. The non-display region DD-NDA surrounds the display region DD-DA. However, an embodiment of the inventive concept is not necessarily limited thereto, and the shape of the display region DD-DA and the shape of the non-display region DD-NDA can vary in other embodiments. For example, in some embodiments, the non-display region DD-NDA is disposed only in those regions that face to each other in the second direction DR2.

The display surface DD-IS is divided into different regions according to a display direction of the image IM. A flat surface region DD-P is parallel to a plane defined by the first direction DR1 and the second direction DR2 perpendicular to the first direction DR1. Curved surface regions DD-C may extend from both sides of the flat surface region DD-P, respectively, and each has a curved outer surface. The image IM can be displayed in the flat surface region DD-P and the curved surface regions DD-C. The display device DD includes a display module DM shown in FIG. 7. The display module DM will be described in detail with reference to FIG. 7.

FIG. 7 is a cross-sectional view taken along line III-III′ in FIG. 6.

Referring to FIGS. 6 and 7, in an embodiment, the display module DM is included in the display device DD of FIG. 6. The display module DM includes a display panel DP, an input sensing part ISP, a reflection preventing layer RPL, a window module WM, a panel protective film PPF, and first and second adhesive layers AL1 and AL2.

The display panel DP may be a light emitting display panel and is not particularly limited. For example, the display panel DP may be an organic light emitting display panel or an inorganic light emitting display panel. An emission layer of the organic light emitting display panel includes an organic luminescent material. An emission layer of the inorganic light emitting display panel may include a quantum dot, a quantum rod, etc. Hereinafter, the display panel DP is described as an organic light emitting display panel.

The input sensing part ISP is disposed on the display panel DP. The input sensing part ISP includes a plurality of sensors that sense an external input by using a capacitance method. The input sensing part ISP can be manufactured directly on the display panel DP during manufacture of the display module DM. However, an embodiment of the inventive concept is not necessarily limited thereto, and in some embodiments, the input sensing part ISP is manufactured as a separate panel from the display panel DP and attached to the display panel DP through an adhesive layer.

The reflection preventing layer RPL is disposed on the input sensing part ISP. The reflection preventing layer RPL can be manufactured directly on the input sensing part ISP during manufacture of the display device DD. However, an embodiment of the inventive concept is not necessarily limited thereto, and in some embodiments, the reflection preventing layer RPL can be manufactured as a separate panel and attached to the input sensing part ISP through an adhesive layer.

The reflection preventing layer RPL is a film that prevents the reflection of external light. The reflection preventing layer RPL reduces the reflectance of external light incident from above the display device DD toward the display panel DP. The external light might not be visible to a user due to the reflection preventing layer RPL.

The window module WM is disposed on the reflection preventing layer RPL. The window module WM protects the display panel DP, the input sensing part ISP, and the reflection preventing layer RPL from an external scratch and impact.

The panel protective film PPF is disposed below the display panel DP. The panel protective film PPF protects a lower portion of the display panel DP. The panel protective film PPF includes a flexible plastic material such as polyethyleneterephthalate (PET).

The first adhesive layer AL1 is disposed between the display panel DP and the panel protective film PPF, and the display panel DP and the panel protective film PPF are bonded to each other through the first adhesive layer AL1. The second adhesive layer AL2 is disposed between the window module WM and the reflection preventing layer RPL, and the window module WM and the reflection preventing layer RPL are bonded to each other through the second adhesive layer AL2.

FIG. 8 illustrates the window module of FIG. 7.

For example, FIG. 8 illustrates the window module WM when viewed in the second direction DR2.

Referring to FIGS. 7 and 8, in an embodiment, the window module WM includes a window WD, an anti-glare layer AGL, an anti-reflective layer ARL, and an anti-fingerprint layer AFL.

The window WD includes a first flat portion WP1, and first curved portions WC1 that extend from both sides of the first flat portion WP1, which are opposite to each other in the first direction DR1. The window WD has a top surface that includes curved surfaces, each of which is convex upward when viewed in the second direction DR2.

The first flat portion WP1 corresponds to the flat surface region DD-P shown in FIG. 6. The first curved portions WC1 correspond to the curved surface regions DD-C shown in FIG. 6.

The window WD includes a glass that is optically transparent. However, an embodiment of the inventive concept is not necessarily limited thereto, and in some embodiments, the window WD includes a synthetic resin film.

The anti-glare layer AGL is disposed on the window WD. The anti-glare layer AGL is disposed on a top surface of the window WD. The anti-glare layer AGL is formed on the window WD using the window deposition apparatus WSM shown in FIG. 1.

The anti-glare layer AGL includes a second flat portion WP2, and second curved portions WC2 that extend from both sides of the second flat portion WP2, which are opposite to each other in the first direction DR1. The anti-glare layer AGL has a top surface that includes curved surfaces, each of which is convex upward when viewed in the second direction DR2.

The second flat portion WP2 is disposed on the first flat portion WP1. The second flat portion WP2 overlaps the first flat portion WP1. The second flat portion WP2 corresponds to the flat surface region DD-P shown in FIG. 6.

Each of the second curved portions WC2 is disposed on a corresponding first curved portion WC1. The second curved portions WC2 overlap the first curved portions WC1, respectively. Each of the first curved portions WC1 has a top surface whose curvature is the same as a curvature of a bottom surface of each of the second curved portions WC2. The second curved portions WC2 correspond to the curved surface regions DD-C shown in FIG. 6.

In addition, the anti-glare layer AGL has a surface that includes protrusions. The protrusions of the anti-glare layer AGL diffusely reflect externally incident light toward the display panel DP. Accordingly, the reflected external light is prevented from being incident into user's eyes, thereby preventing glare.

The anti-reflective layer ARL is disposed on the anti-glare layer AGL. The anti-reflective layer ARL is disposed on a top surface of the anti-glare layer AGL. The anti-reflective layer ARL is formed on the anti-glare layer AGL using the window deposition apparatus WSM shown in FIG. 1.

The anti-reflective layer ARL includes a third flat portion WP3, and third curved portions WC3 that extend from both sides of the third flat portion WP3, which are opposite to each other in the first direction DR1. The anti-reflective layer ARL has a top surface that includes curved surfaces, each of which is convex upward when viewed in the second direction DR2.

The third flat portion WP3 is disposed on the second flat portion WP2. The third flat portion WP3 overlaps the first flat portion WP1 and the second flat portion WP2. The third flat portion WP3 corresponds to the flat surface region DD-P shown in FIG. 6.

Each of the third curved portions WC3 is disposed on a corresponding second curved portion WC2. Each of the third curved portions WC3 respectively overlaps each of the first curved portions WC1 and each of the second curved portions WC2. Each of the second curved portions WC2 has a top surface whose curvature is the same as a curvature of a bottom surface of each of the third curved portions WC3. The third curved portions WC3 correspond to the curved surface regions DD-C shown in FIG. 6.

The anti-reflective layer ARL includes at least one of a silica dioxide (SiO2) or a titanium dioxide (TiO2). However, an embodiment of the inventive concept is not necessarily limited thereto, and in an embodiment, the anti-reflective layer ARL includes magnesium fluoride (MgF2).

The light that is externally incident toward the display panel DP is not reflected by the anti-reflective layer ARL. For example, a phase of the light reflected from the window WD and a phase of the light reflected from the anti-reflective layer ARL differ from each other. The light reflected from the window WD and the light reflected from the anti-reflective layer ARL destructively interfere with each other. Accordingly, the anti-reflective layer ARL reduces the reflectance of the window module WM, and prevents the reflected external light from being visible to a user.

The anti-fingerprint layer AFL is disposed on the anti-reflective layer ARL. The anti-fingerprint layer AFL is disposed on a top surface of the anti-reflective layer ARL. The anti-fingerprint layer AFL is formed on the anti-reflective layer ARL using the window deposition apparatus WSM shown in FIG. 1.

The anti-fingerprint layer AFL includes a fourth flat portion WP4, and fourth curved portions WC4 that extend from both sides of the fourth flat portion WP4, which are opposite to each other in the first direction DR1. The anti-fingerprint layer AFL has a top surface that includes curved surfaces, each of which is convex upward when viewed in the second direction DR2.

The fourth flat portion WP4 is disposed on the third flat portion WP3. The fourth flat portion WP4 overlaps the first flat portion WP1, the second flat portion WP2, and the third flat portion WP3. The fourth flat portion WP4 corresponds to the flat surface region DD-P shown in FIG. 6.

Each of the fourth curved portions WC4 is disposed on a corresponding third curved portion WC3. Each of the fourth curved portions WC4 overlaps the first, second, and third curved portions WC1, WC2 and WC3. Each of the third curved portions WC3 has a top surface whose curvature is the same as a curvature of a bottom surface of each of the fourth curved portions WC4. The fourth curved portions WC4 correspond to the curved surface regions DD-C shown in FIG. 6.

The anti-fingerprint layer AFL includes a water-repellent coating. For example, the anti-fingerprint layer AFL includes a fluorine coating layer. Accordingly, the anti-fingerprint layer AFL is water- and oil-repellent, and prevents a user's fingerprint from remaining on a surface of the window module WM and prevents contaminants from attaching to the window module WM.

FIG. 8 illustrates the anti-glare AGL, the anti-reflective layer ARL, and the anti-fingerprint layer AFL as being disposed on the window WD, but an embodiment of the inventive concept is not necessarily limited thereto. For example, any one layer may be omitted. For another example, in addition to the anti-glare layer AGL, the anti-reflective layer ARL, and the anti-fingerprint layer AFL, another layer may be additionally deposited on the window WD.

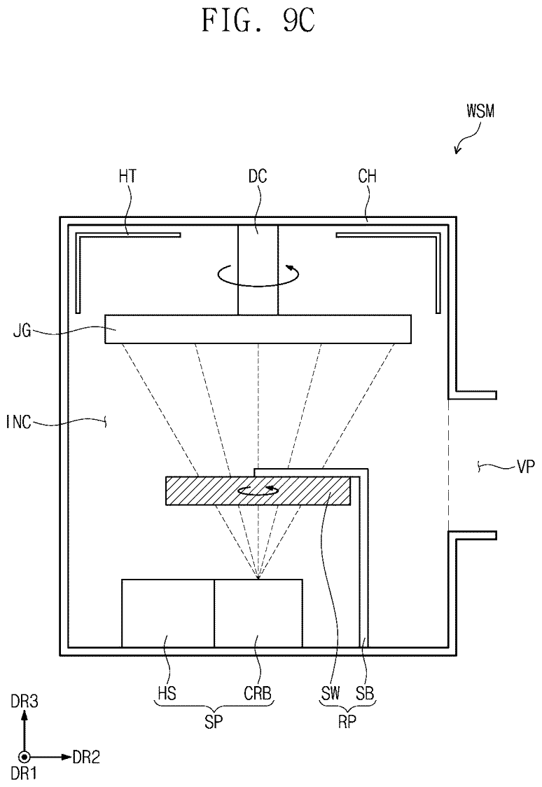

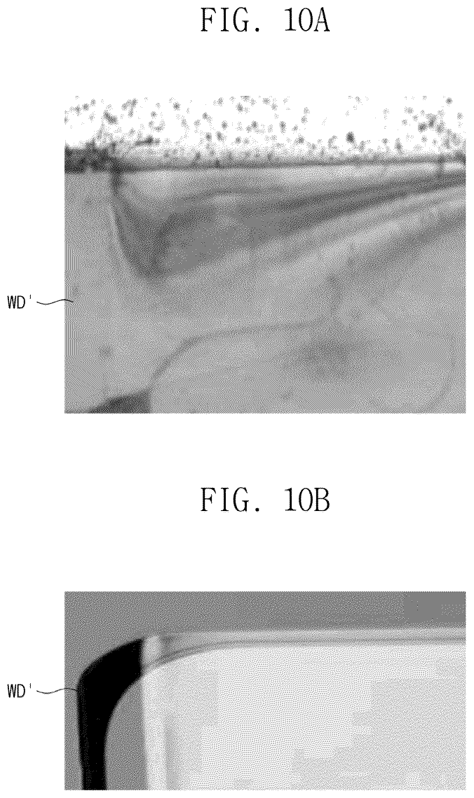

FIGS. 9A to 9C illustrate deposition of the window module illustrated in FIG. 8. FIG. 10A illustrates a window module according to comparative example. FIG. 10B illustrates a window module manufactured by a window deposition apparatus according to an embodiment of the inventive concept.

For example, FIG. 9A is a plan view, FIG. 9B is a cross-sectional view taken along line II-II′ in FIG. 3, and FIG. 9C illustrates a window deposition apparatus WSM when viewed in the first direction DR1.

For example, FIGS. 10A and 10B illustrate rear surfaces of windows WD and WD′, respectively.

The window deposition apparatus WSM, the seating part JG, and the window WD that are illustrated in FIGS. 9A to 9C, are the same as or similar to the window deposition apparatus WSM and the seating part JG that are illustrated in FIGS. 1 to 5, and the window WD illustrated in FIG. 8, respectively. Thus, repeated descriptions thereof may be omitted or simplified.

Referring to FIGS. 9A and 9B, in an embodiment, the windows WD are disposed in open portions WOP formed in the seating part JG. Hereinafter, one seating unit ANU and one window WD will be described for convenience of explanation.

The window WD is disposed in the open portion WOP. The window WD is disposed in the open portion WOP along the guide surface GDP. The window WD is disposed in the open portion WOP while being inverted upside down. A front surface of the window WD is directed downward. The window WD is disposed so that a rear surface of the window WD is positioned at a higher level than the front surface of the window WD.

The open portion WOP exposes a portion of the window WD from the seating part JG. For example, the window WD is in contact with the inner surface ISD of the seating part JG that defines the open portion WOP. Each of first curved portions WC1 has a portion disposed on the seating surface ANP. Accordingly, the window WD is in close contact with the seating part JG. In the window WD, the first flat portion WP1 and a portion of each of the first curved portions WC1 are exposed by the seating part JG.

Referring to FIGS. 8, 9B and 9C, in an embodiment, the window WD is disposed on the seating part JG and then, the seating part JG is disposed within a chamber CH. The seating part JG is connected to the driving part DC. The driving part DC rotates the seating part JG around a rotary axis parallel to the third direction DR3.

When the seating part JG is disposed within the chamber CH, the heat source HS of the spray part SP heats a deposition material in the crucible CRB. For example, the heat source HS heats the crucible CRB through one of an e-beam evaporation method that converts kinetic energy of electrons into thermal energy, or a sputtering method that converts electrical energy of a plasma into kinetic energy.

The deposition material in the crucible CRB is heated by the heat source HS and evaporated. The deposition material may be used for forming the anti-glare layer AGL, the anti-reflective layer ARL, and the anti-fingerprint layer AFL. When the deposition material has evaporated into a gaseous state, the wing part SW disposed on the spray part SP rotates. The deposition material is uniformly deposited on the seating part JG by the wing part SW.

The deposition material is deposited on the window WD disposed within the open portion WOP. The deposition material is deposited on the portion of the window WD that is exposed by the seating part JG. The deposition material moves along the inducing surface INP toward the window WD. The deposition material is deposited on the front surface of the window WD.

Different deposition materials can be deposited multiple times on the front surface of the window WD to manufacture the window module WM in FIG. 8.

Referring to FIGS. 9B, 9C and 10A, in an embodiment, when the window WD is not seated on the seating part JG, the gaseous deposition material is deposited on each of the front surface and the rear surface of the window WD. For example, stains are generated on the rear surface of the window WD′ as illustrated in FIG. 10A. The stains generated on the rear surface cause an outer appearance defect of the window WD′. In addition, the stains reduce the adhesion between the window WD′ and the second adhesive layer AL2 (see FIG. 7) to cause a defect of the display device DD (see FIG. 6).

However, when the window deposition apparatus WSM according to an embodiment of the inventive concept is used to deposit the deposition material on the window WD, the window WD is in close contact with the inner surface ISD of the seating part JG. Accordingly, the gaseous deposition material is deposited on the front surface of the window WD and is not deposited on the rear surface of the window WD. Thus, the stains are not generated, which prevents outer appearance defects of the window WD. In addition, the reduction in adhesion between the window WD and the second adhesive layer AL2 (see FIG. 7) is prevented, which prevents defects of the display device DD (see FIG. 6).

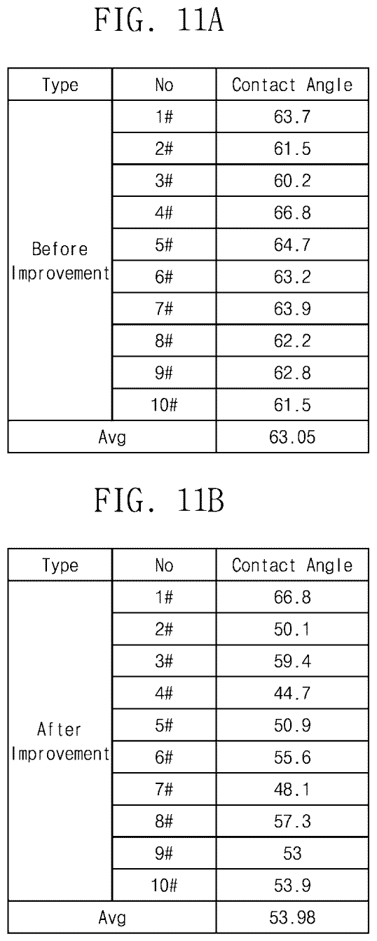

FIGS. 11A and 11B are tables that illustrate adhesion between a window module and a second adhesive layer.

For example, FIG. 11A shows experimental data of the window module WM (see FIG. 7) according to a Comparative Example, and FIG. 11B shows experimental data of the window module WM (see FIG. 7) manufactured by a window deposition apparatus according to an embodiment of the inventive concept.

Referring to FIGS. 7, 11A and 11B, an experiment on adhesion between the window module WM and the second adhesive layer AL2 is carried out through a contact angle experiment. The contact angle experiment is when a liquid droplet is dropped onto a rear surface of the window module WM and then, a contact angle between the rear surface of the window module WM and the liquid droplet is measured. The contact angle is defined as an angle obtained by measuring an angle between a liquid surface and the window rear surface WM from the inside of the liquid. As a hydrophilic property of the window surface WM decreases, the contact angle may increase. For example, as the contact angle increases, the adhesion between the rear surface of the window module WM and the second adhesive layer AL2 decreases.

Referring to FIGS. 8 and 11A, in an embodiment, when the deposition material is deposited on the rear surface of the window module WM, an average contact angle is about 63.05 degrees as shown in FIG. 11A. The results show that the hydrophilic property of the rear surface of the window module WM decreases. Accordingly, the adhesion between the window module WM and the second adhesive layer AL2 is reduced.

Referring to FIGS. 8, 9B and 11B, in an embodiment, when the window deposition apparatus according to an embodiment of the inventive concept is used to manufacture the window module WM, the window WD is in close contact with the inner surface ISD of the seating part JG. Accordingly, the deposition material is not deposited on a rear surface of the window WD. As shown in FIG. 11B, an average contact angle is about 53.98 degrees. The results show that the hydrophilic property of the rear surface of the window module WM does not decrease. Accordingly, the adhesion between the window module WM and the second adhesive layer AL2 is not reduced, which prevents defects of the display device DD (see FIG. 6).

According to an embodiment of the inventive concept, an inner surface of a seating part that defines an open portion includes a first inner surface, a second inner surface disposed on the first inner surface, a seating surface that connects an upper end of the first inner surface and a lower end of the second inner surface to each other, an inducing surface that connects the first inner surface and a bottom surface of the seating part to each other, and a guide surface that connects the second inner surface and a top surface of the seating part to each other. A window is disposed within the open portion. The window is in close contact with the inner surface of the seating part. Accordingly, a deposition material is deposited on a front surface of the window and not on a rear surface of the window.

Although embodiments of the present disclosure have been described, it is understood that embodiments of the present disclosure should not be limited thereto, but that various changes and modifications can be made by one ordinary skilled in the art within the spirit and scope of the present disclosure as hereinafter claimed. Rather, embodiments set forth herein are provided so that this disclosure will be thorough and complete, and will fully convey the scope of the inventive concept to those skilled in the art.

What is claimed is:

1. A window deposition apparatus, comprising:
a chamber;
a seating part disposed within the chamber and on which a window is disposed, and in which an open portion that exposes a portion of the window is formed; and
a spray part disposed within the chamber and that faces a bottom surface of the seating part,
wherein an inner surface of the seating part that defines the open portion comprises:
a first inner surface that defines the open portion;
an inducing surface that connects the first inner surface and the bottom surface of the seating part to each other;
a second inner surface disposed on the first inner surface; and
a guide surface that connects the second inner surface and a top surface of the seating part to each other,
wherein the first inner surface protrudes inward than the second inner surface.

2. The window deposition apparatus of claim 1, wherein the inner surface of the seating part further comprises a seating surface that connects an upper end of the first inner surface and a lower end of the second inner surface to each other.

3. The window deposition apparatus of claim 2, wherein the window is seated on the seating surface.

4. The window deposition apparatus of claim 2, wherein the seating surface comprises:
first seating surfaces that extend in a first direction when viewed in a plan view; and
second seating surfaces that extend in a second direction that crosses the first direction, when viewed in the plan view.

5. The window deposition apparatus of claim 4, wherein each of the first seating surfaces has a width in the second direction of about 0.2 mm to about 0.3 mm when viewed in the plan view.

6. The window deposition apparatus of claim 4, wherein each of the second seating surfaces has a width the first direction of about 0.15 mm to about 0.25 mm in when viewed in the plan view.

7. The window deposition apparatus of claim 4, wherein the guide surface has a height that gradually decreases toward the second inner surface.

8. The window deposition apparatus of claim 7, wherein the guide surface has a width of about 3 mm to about 7 mm when viewed in the plan view.

9. The window deposition apparatus of claim 7, wherein the guide surface has an angle in a third direction of about 20 degrees or greater and less than about 90 degrees, wherein the third direction crosses a plane defined by the first direction and the second direction.

10. The window deposition apparatus of claim 1, wherein the inducing surface has a height that gradually increases toward the first inner surface.

11. The window deposition apparatus of claim 10, wherein a thickness from the bottom surface of the seating part to a boundary between the inducing surface and the first inner surface is about 3 mm to about 5 mm.

12. The window deposition apparatus of claim 11, wherein the inducing surface has an angle with respect to the bottom surface of the seating part of about 20 degrees or greater and less than about 90 degrees.

13. The window deposition apparatus of claim 1, further comprising a driving part disposed on the seating part within the chamber,
wherein the seating part has a fan shape, and the seating part is rotatably coupled to the driving part.

14. The window deposition apparatus of claim 1, further comprising a rotary part disposed within the chamber between the seating part and the spray part.

15. The window deposition apparatus of claim 1, wherein the spray part comprises:
a crucible in which a deposition material is disposed; and
a heat source that heats the deposition material.

16. A window deposition apparatus, comprising:
a chamber;
a seating part disposed within the chamber and on which a window is disposed, and in which an open portion that exposes a portion of the window is formed; and
a spray part disposed within the chamber and that faces a bottom surface of the seating part,
wherein an inner surface of the seating part that defines the open portion comprises:
a first inner surface configured to define the open portion;
a second inner surface disposed on the first inner surface; and
a seating surface that connects an upper end of the first inner surface and a lower end of the second inner surface to each other,
wherein the first inner surface protrudes inward from the second inner surface.

17. The window deposition apparatus of claim 16, wherein the seating surface comprises:
first seating surfaces that extend in a first direction when viewed in a plan view; and
second seating surfaces that extend in a second direction that crosses the first direction, when viewed in the plan view.

18. The window deposition apparatus of claim 17, wherein each of the first seating surfaces has a width in the second direction of about 0.2 mm to about 0.3 mm, when viewed in the plan view, and
each of the second seating surfaces has a width in the first direction of about 0.15 mm to about 0.25 mm, when viewed in the plan view.

19. The window deposition apparatus of claim 17, wherein the inner surface of the seating part further comprises an inducing surface that connects the bottom surface of the seating part and the first inner surface to each other,
wherein the inducing surface has an angle with respect to the bottom surface of the seating part of about 20 degrees or greater and less than about 90 degrees, and
a thickness from the bottom surface of the seating part to a boundary between the inducing surface and the first inner surface is about 3 mm to about 5 mm.

20. The window deposition apparatus of claim 17, wherein the inner surface of the seating part further comprises a guide surface that connects a top surface of the seating part and the second inner surface to each other,
wherein the guide surface has a width of about 3 mm to about 7 mm when viewed in the plan view, and
the guide surface has an angle in a third direction of about 20 degrees or greater and less than about 90 degrees, wherein the third direction crosses a plane defined by the first direction and the second direction.
